(19) United States
(12) Patent Application Publication
(10) Pub. No.: US 2011/0214718 A1
(43) Pub. Date: Sep. 8, 2011

(54) MANUFACTURING OF ELECTRODE

(75) Inventor: ISAO HAYASHI, Tokyo (JP)

(73) Assignee: E.I. DU PONT DE NEMOURS AND COMPANY, Wilmington, DE (US)

(21) Appl. No.: 12/715,741

(22) Filed: Mar. 2, 2010

(51) Int. Cl. H01L 31/0224; B05D 5/12; H01L 21/441

(52) U.S. Cl. 136/252; 427/58; 438/652; 257/E21.477; 257/E31.124

(57) ABSTRACT

In the present invention, to keep the conductive paste from flowing, an organic layer is formed on the substrate, following which the conductive paste is printed and fired. An electrode could be formed with a method comprising steps of: applying an organic paste onto one side of a substrate so as to form an organic layer; applying a conductive paste onto the organic layer; and firing the conductive paste so as to form an electrode and burn off the organic layer.

### FIELD OF THE INVENTION

This invention relates to improvement of manufacturing method of an electrode formed in an electric device.

### BACKGROUND OF THE INVENTION

Methods for applying and firing conductive pastes are often used in the production of electrodes for electronic components. In conductive pastes, holding down the viscosity to a certain degree is necessary for applying, but a viscosity that is too low will result in “sag”—spreading of the paste on the surface of the substrate after applying. When such sagging arises, it is difficult to form fine electrodes or high aspect ratio electrodes that are desired. For instance, the manufacturing process of the silicon solar cells typically includes the formation of electrode by use of conductive paste generally including conductive powder, glass frit, organic medium. Since the electric generating capacity of solar cells increases as the light-receiving area thereof increases, it is preferable for the front electrode formed on the light-receiving area to have a narrow line width. However, if the line width is merely narrowed, a decrease in cross-sectional area of the electrode will end up increasing electrode resistance and will thus end up decreasing optical conversion efficiency. Therefore, there is a need to increase the height, that is, to increase the aspect ratio.

The following prior art exists on electrodes in which sagging has been suppressed.

JP2006-054374 discloses a method for forming an electrode having a high aspect ratio by forming a groove for electrode formation on a substrate and applying the aforementioned conductive paste under reduced pressure into this groove for electrode formation, thereby forming the electrode.

JP2007-019106 discloses a method for forming an electrode having a high aspect ratio by using a conductive paste containing an adjusted quantity of organic matter and silver powder and having suitable viscosity and thixotropy.

JP2009-246277 discloses a conductive paste for a solar cell. This conductive paste includes ethyl cellulose having a low degree of ethoxylation of 45 to 47% in a proportion of at least 60% of the overall resin. Because such a conductive paste has increased thixotropy, spreading of the paste on the surface where it has been applied can be advantageously suppressed while ensuring suitable flow properties during squeezing.

The present invention, unlike the foregoing prior art, achieves a high aspect ratio in electrodes through a method of manufacture-based approach.

### SUMMARY OF THE INVENTION

An objective of this present invention is to provide an improvement of manufacturing method of an electrode that enable to produce an electrode with high aspect ratio. In the present invention, to keep the conductive paste from flowing, an organic layer is formed on the substrate, following which the conductive paste is printed and fired.

An aspect of the present invention is a method of manufacturing an electrode, comprising steps of: applying an organic paste onto one side of a substrate so as to form an organic layer; applying a conductive paste onto the organic layer; and firing the conductive paste so as to form an electrode and burn off the organic layer.

Another aspect of the present invention is an electrode on a light-receiving side of a solar cell, which is formed with a method of manufacturing an electrode, comprising steps of: applying an organic paste onto one side of a substrate so as to form an organic layer; applying a conductive paste onto the organic layer; and firing the conductive paste so as to form an electrode and burn off the organic layer.

If the present invention is used, an electrode having a high aspect ratio can be formed.

### BRIEF DESCRIPTION OF THE DRAWINGS

FIG. 1 is a process flow diagram illustrating the fabrication of an electrode of a solar cell.

FIG. 2 shows an electrode paste printed and dried on a substrate formed by a conventional method (FIG. 2A) and an electrode formed by the present invention (FIG. 2B) in the example described below.

### DETAILED DESCRIPTION OF THE INVENTION

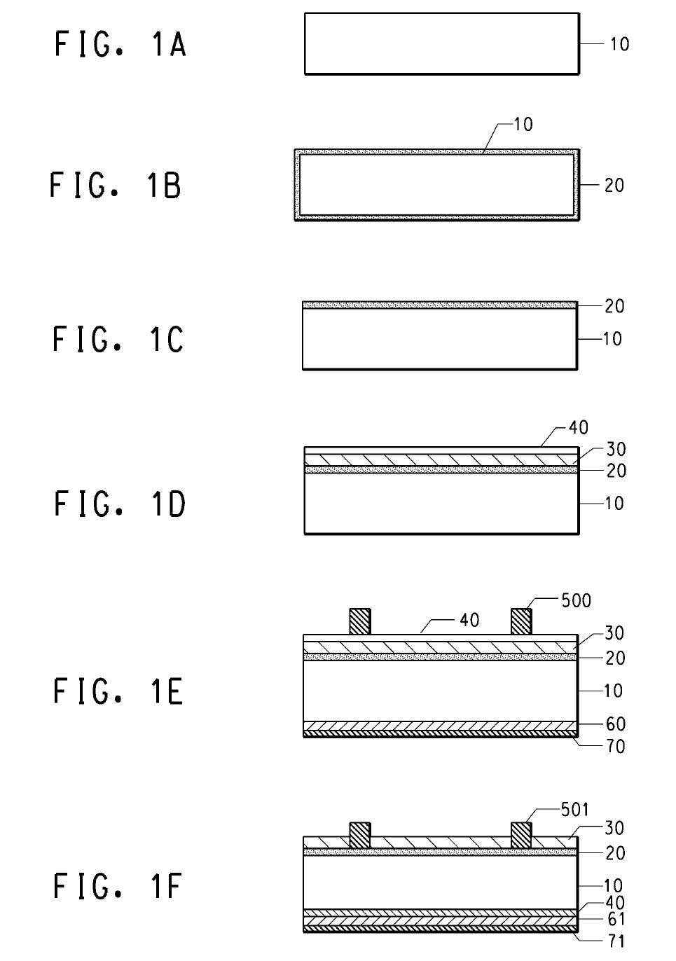

Firstly, referring to the FIG. 1, an embodiment of the present invention of manufacturing process of an electrode on a light receiving surface of photovoltaic cell is illustrated.

FIG. 1A shows a p-type silicon substrate, 10. In FIG. 1B, an n-type diffusion layer, 20, of the reverse conductivity type is formed by the thermal diffusion of phosphorus (P) or the like. Phosphorus oxychloride (POCl₃) is commonly used as the phosphorus diffusion source. In the absence of any particular modification, the diffusion layer, 20, is formed over the entire surface of the silicon substrate, 10. This diffusion layer typically has a sheet resistivity on the order of several tens of ohms per square, and a thickness of about 0.3 to 0.5 μm.

After protecting one surface of this diffusion layer with a resist or the like, as shown in FIG. 1C, the diffusion layer, 20, is removed from most surfaces by etching so that it remains only on one main surface. The resist is then removed using an organic solvent or the like.

Next, a silicon nitride layer, 30, is formed as an anti-reflection coating on the n-type diffusion layer, 20, to a thickness of typically about 700 to 900 Å in the manner shown in FIG. 1D by a process such as plasma chemical vapor deposition (CVD). The organic paste is then applied onto the silicon nitride layer, 30. The organic paste can be applied either partially or all over one side of the substrate. When applying partially, it is necessary to cover at least an area to which the conductive paste is applied. The method of application is exemplified by screen printing. The applied organic paste is dried, thereby forming an organic layer, 40.

As shown in FIG. 1E, a conductive paste, 500, is screen printed on the light-receiving side which has, organic layer, 40. In addition, a backside silver or silver/aluminum paste, 70, and an aluminum paste, 60, are then screen printed and successively dried on the backside of the substrate. Firing is then carried out in a furnace at a temperature of approximately less than 1000° C. for several seconds or for several minutes. The firing time is preferably from 30 seconds to 3 minutes. At a firing time of 30 seconds or less, sintering of the electrode may not proceed as a result of which the desired electrical properties may not emerge. On the other hand, at a firing time of more than 3 minutes, damage may occur to the semiconductor substrate. It is more preferable for the sintering time not exceed 2 minutes. Of this sintering time, the length of time during which the sintering temperature is 700° C. or above is preferably from 1 to 10 seconds, and more preferably not more than 5 seconds. The reason is to lower the possibility of the semiconductor substrate incurring damage due to elevated temperatures.

Consequently, as shown in FIG. 1F, aluminum diffuses from the aluminum paste into the silicon substrate, 10, as a dopant during firing, forming a p+ layer containing a high concentration of aluminum dopant. This layer is generally called the back surface field (BSF) layer (not shown in FIG.), and helps to improve the energy conversion efficiency of the solar cell.

The aluminum paste is transformed by firing from a dried state, 60, to an aluminum back electrode, 61. The backside silver or silver/aluminum paste, 70, is fired at the same time, becoming a silver or silver/aluminum back electrode, 71. During firing, the boundary between the back side aluminum and the back side silver or silver/aluminum assumes an alloy state, and is connected electrically as well. The aluminum electrode accounts for most areas of the back electrode, owing in part to the need to form a p+ layer. Because soldering to an aluminum electrode is impossible, a silver back electrode is formed over portions of the back side as an electrode for interconnecting solar cells by means of copper ribbon or the like. In addition, the front electrode-forming conductive paste, 500, sinters and penetrates through the silicon nitride layer, 30, during firing, and is thereby able to electrically contact the n-type layer, 20. This type of process is generally called “fire through”. This fired through state is apparent in layer, 501 of FIG. 1F. During sintering, the organic layer, 40, burns off. In the foregoing description of this embodiment, a p-base type substrate which includes a p-type silicon substrate, 10, and an n-type diffusion layer, 20 was used. However, it is also possible to use an n-base type substrate. Moreover, the type of substrate is preferably, but not necessarily, a semiconductor substrate such as a polycrystalline silicon substrate or a single-crystal silicon substrate.

The electrode forming method of the invention is not limited to the above-mentioned use in solar cells. For example, it is also possible to use this method in forming fine circuits which is required on an electronic device such as displays, semiconductor devices and capacitors. Solar cell electrodes are especially preferred. As explained above, in solar cell electrodes, to increase the light-receiving surface area, a high aspect ratio is desired. By using the present invention, decrease of the aspect ratio of an electrode after printing is prevented and an electrode having a high aspect ratio is formed. As a result, a solar cell having a high energy conversion efficiency is manufactured. Because improvement of optical conversion efficiency through an increase in the light-receiving area can be expected.

Next, the organic layer is described in detail.

In this invention, “organic layer” refers to a layer which is composed of an organic compound alone or a mixture of an organic compound with an organic solvent, and which burns off during sintering. The term “burn off” used herein does not require that the entire organic layer vanish due to sintering, and encompasses also cases where a portion of the organic layer remains. However, from the standpoint of electrical connection between the substrate and the electrode, the organic layer remaining after sintering is preferably not more than 5 wt %, and more preferably not more than 3 wt %, based on the weight of the organic layer after drying and before sintering.

The type of organic compound used in this invention is not subject to any particular limitation, although the use of a resin or wax which is commonly distributed and readily available is preferred. As used herein, “resin” refers to a polymeric compound obtained by bonding one or more monomer, and may be either a natural resin or a synthetic resin. Also, “wax” refers to an ester of a higher fatty acid and a higher monohydric alcohol. The organic layer is formed by applying and drying an organic paste which includes the organic compound and has a certain degree of viscosity for applying. As a kind of organic resin, epoxy resin, polyester resin, ethylene-vinyl acetate copolymer, polyvinyl alcohol, polyvinyl vutyral, polyimide, polyamide and modified cellulose such as a polyvinyl chloride acetate copolymer, phenol resin, an acrylic resin, ethyl cellulose, nitrocellulose, can be preferably used. The ethyl cellulose with a good solvent solubility is preferably used in this present invention. Ethyl cellulose is preferable because it has solubility in many types of organic solvents and also from the standpoint of safety because it is chemically stable. In addition, it can be used in a wide range of fields, and is thus inexpensive and readily available.

In the present invention, a solvent can be additionally used as a viscosity adjuster as necessary. Any arbitrary solvent can be used. Preferable solvents include aromatic, ketone, ester, ether, glycol, glycol ether and glycol ester. Butyl carbitol (CAS No. 112-34-5), which is a mixture of butyl diglycol, diethylene glycol and monobutyl ether, is especially preferable because it also has a good ethyl cellulose solubility. In addition, it is widely distributed as a commercial product, and thus readily available.

In case of screen printing is taken, high-boiling solvent such as ethyl carbitol acetate, butyl cellosolve acetate, cyclohexanone, benzyl alcohol, terpineol, butyl carbitol are favorably used. In case of using ethyl cellulose, the content of the resin is preferably 1-20 weight percent (wt %) based on the total weight of the organic paste. And the content of the solvent is preferably 80-99 wt % based on the total weight of the organic paste.

A thickener and/or stabilizer and/or other typical additives may be added to the organic paste to make the organic layer of the present invention. Examples of other typical additives that can be added include dispersants and viscosity adjusters. The amount of additive is determined dependent upon the characteristics of the ultimately required organic paste. The amount of additive can be suitably determined by a person with ordinary skill in the art. Furthermore, a plurality of types of additives may also be added. As is explained below, the organic paste of the present invention has a viscosity within a predetermined range. A viscosity adjuster can be added as necessary to impart a suitable viscosity to the organic paste. Although the amount of viscosity adjuster added changes dependent upon the viscosity of the ultimate organic paste, it can be suitably determined by a person with ordinary skill in the art.

The viscosity of the organic paste used in the present invention is not subject to any particular limitation, provided it can be applied (coated) onto the substrate. In cases where the organic paste is applied by screen printing, the viscosity of the organic paste is preferably from 10 to 200 Pa·s at 25° C. At an organic paste viscosity of less than 10 Pa·s, the shape retention of the printed pattern obtained decreases, whereas at more than 200 Pa·s, there is a possibility that the organic paste will have difficulty passing through the screen printing mask. Taking these considerations into account, the viscosity at 25° C. is more preferably from 10 to 100 Pa·s. In the present patent application, in cases where significant differences in viscosity arise depending on the measurement device, a DV-I prime 2HAT viscosimeter (Brookfield Co., Ltd.) is employed.

The thickness of the organic layer is adjusted according to the firing conditions, and thus is not subject to any particular limitation. However, particularly in a solar cell electrode forming process in which the firing time is short, given that the conditions for firing the conductive paste are generally a temperature of at least 100° C. and a period of from 20 to 60 seconds, with a peak temperature of from 400 to 1,000° C., the organic layer burns off under the preferred conditions. Therefore, the lower limit value in the organic layer thickness after drying is preferably 1 μm, and more preferably 2 μm. At less than 1 μm, the organic layer burns off soon after the start of firing, which may reduce the conductive paste flow-suppressing effect. The upper limit value in the organic layer thickness after drying is preferably 30 μm, and more preferably 10 μm. At an organic layer thickness of more than 30 μm, the organic layer remains unburned between the electrode and the substrate and may therefore end up increasing the contact resistance. In the present invention, organic layer thickness values measured by a Surfcom 480A (Accreteck) are used.

### EXAMPLES

Examples of the electrode of the present invention are described herein below.

### Conductive Paste Preparation

Used material in the conductive paste preparation was as follows. 76% of spherical silver powder, 2% of glass frit and 5 wt % of zinc oxide powder were dispersed into 17 wt % of organic medium to form a conductive paste. When well mixed, the conductive paste was repeatedly passed through a 3-roll mill for at progressively increasing pressures from 0 to 400 psi. The gap of the rolls was adjusted to 1 mm.

### Organic Paste Preparation

Butyl carbitol (Product No. 040-19355; sold by Hiroshima-Wako Co., Ltd.) was poured into a stainless steel jar, and ethyl cellulose powder was added under stirring. The amount of ethyl cellulose added was set to 11 wt % based on the total weight of the organic paste. The mixed solution of the butyl carbitol and the ethyl cellulose powder was stirred for 3 hours while being held at 80° C., thereby rendering it into an organic paste. This organic paste had a viscosity at 25° C. of 19 Pa·s. The viscosity was measured using a DV-I prime 2HAT viscosimeter (Brookfield Co., Ltd.)

### Method of Forming an Electrode for Solar Cell

Firstly, silicon (Si) wafers with SiNx antireflection coatings were prepared. The size of the Si wafers were 38 mm square and 0.2 mm thickness. An electrode was formed on the silicon wafer by using the conductive paste and organic paste described above. 0.04 g of the organic paste was printed all over the front side of the Si wafer to form the organic layer with 36 mm square area. The organic paste was dried under 150° C. for 5 minutes to form an organic layer. The thickness of the organic layer was 3 um.

Then the conductive paste prepared as above was screen printed through a mask with pattern of six lines (length 16 mm, width 90 μm, thickness 25 μm) on the organic layer. Then the printed conductive pattern were dried under 150° C. for 5 minutes. The dried conductive patterns on the wafers and organic layers was fired in an IR heating belt furnace in air. The maximum set temperature was around 770° C. and its In-Out time was 115 sec. The organic layer burned out to disappear after firing and an electrode was formed on the wafer substrate.

Also, for the sake of comparison, an electrode was formed by applying the conductive paste directly onto the substrate without providing an organic layer.

### Test Procedure of Electrode Width

The electrode width were measured after firing with a meter by OPTELICS C130 from Laser technology Co., Ltd. To obtain the measured values, measurements were taken near the center of each line in a 6-line pattern, and the mean of these values was determined.

### Results

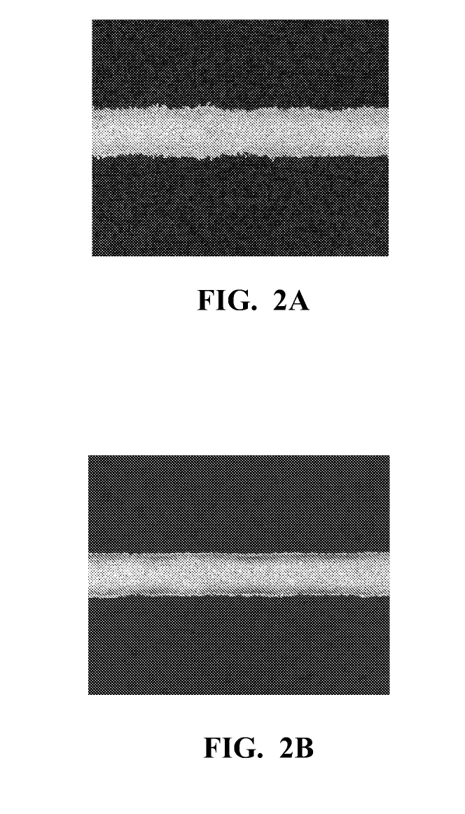

In cases where the conductive paste was applied directly onto the substrate, the linewidth in the pattern was 138 μm after drying. By contrast, in cases where the conductive paste was applied after first forming an organic layer, the linewidth in the pattern was 109 μm after drying. The linewidth in the pattern after firing was 138 μm in the former case while the linewidth in the pattern after firing was 94 μm in the latter case. Although formation was carried out using a mask having the same line pattern, the electrode width of the former was wider than that of the latter. In addition, a difference was also observed in the appearance of the lines after drying. Bleeding was observed in the lines after drying when the conductive paste was applied directly onto the substrate (FIG. 2A), whereas bleeding was not observed when the conductive paste was applied after the formation of an organic layer (FIG. 2B).

From the above, it was possible to keep the electrode width from increasing by forming an organic layer on the substrate, then applying the conductive paste. This invention makes it possible to form fine electrodes or to form electrodes having a high aspect ratio.

1. A method of manufacturing an electrode, comprising steps of:
applying an organic paste onto one side of a substrate so as to form an organic layer;
applying a conductive paste onto the organic layer; and
firing the conductive paste so as to form an electrode and burn off the organic layer.

2. The electrode manufacturing method of claim 1, wherein the organic paste includes resin, wax or mixture thereof.

3. The electrode manufacturing method of claim 1, wherein the substrate is a semiconductor substrate.

4. An electrode formed using the electrode manufacturing method of claim 1.

5. An electrode on a light-receiving side of a solar cell, which is formed using the electrode manufacturing method of claim 1.
